(19) United States
(12) Patent Application Publication
(10) Pub. No.: US 2026/0018428 A1
(43) Pub. Date: Jan. 15, 2026

(54) METHOD AND DEVICE FOR MANUFACTURING AN ELECTRONIC COMPONENT AND ELECTRONIC COMPONENT FORMED THEREBY

(71) Applicant: Murata Manufacturing Co., Ltd., Nagaokakyo-shi (JP)

(72) Inventors: Koichi KANRYO, Nagaokakyo-shi (JP); Katsuki NAKANISHI, Nagaokakyo-shi (JP); Kohei SUZUKI, Nagaokakyo-shi (JP); Koji TAKAKI, Nagaokakyo-shi (JP)

(73) Assignee: Murata Manufacturing Co., Ltd., Nagaokakyo-shi (JP)

(21) Appl. No.: 19/327,436

(22) Filed: Sep. 12, 2025

Related U.S. Application Data
(63) Continuation of application No. PCT/JP2024/008065, filed on Mar. 4, 2024.

(30) Foreign Application Priority Data
Mar. 13, 2023 (JP) 2023-038951

(51) Int. Cl. H01L 21/56; H01L 21/67; H01L 23/31

(52) U.S. Cl. CPC H01L 21/566; H01L 21/561; H01L 21/67126; H01L 23/3121

(57) ABSTRACT

An electronic component manufacturing method for obtaining an electronic component in which a resin molded body and an object are integrally formed and the resultant device is provided. The method includes forming a resin distribution set by feeding a resin material in granular, powder, or liquid form onto a release film in a resin receiving portion to create a non-uniform distribution, wherein the resin material is thicker at a predetermined location than at other locations. The resin distribution set including the release film and placing the resin distribution set onto a lower mold such are lifted and placed over a cavity in a lower mold. The release film covers an inner surface of the cavity, positioning the resin material in the cavity. The resin material is compression-molded with the object in contact with the resin material located in the cavity to obtain the device.

### CROSS-REFERENCE TO RELATED APPLICATIONS

This is a continuation application of PCT International Patent Application No. PCT/JP2024/008065 filed on Mar. 4, 2024, which claims priority to Japanese patent application JP 2023-038951, filed Mar. 13, 2023, the entire contents of each of which being incorporated herein by reference.

### TECHNICAL FIELD

The present disclosure relates to an electronic component manufacturing method and manufacturing device.

### BACKGROUND ART

Japanese Patent No. 5153509 (PTL 1) discloses an electronic component compression molding method and a mold device. In PTL 1, the inside of a through hole of a resin receiving plate positioned on a release film serves as a plate resin receiving portion, and granular resin is charged into the plate resin receiving portion. By moving the resin receiving plate with a horizontal-moving leveling mechanism, the granular resin is leveled to a uniform thickness in the plate resin receiving portion.

Japanese Patent No. 6310773 (PTL 2) discloses a resin molding device and a resin molding method. In PTL 2, in a state where a resin receiving frame is positioned on a release film and a resin material is charged into the resin receiving frame, these are collectively held, and the release film is pushed downward by lowering a raising and lowering member positioned in the resin receiving frame relative to the resin receiving frame. By doing so, the resin material and the release film are collectively fed into the cavity of a lower mold.

### CITATION LIST

### Patent Literature

PTL 1: Japanese Patent No. 5153509
PTL 2: Japanese Patent No. 6310773

### SUMMARY

### Technical Problems

As disclosed in PTL 1, since the granular resin is leveled to a uniform thickness in the plate resin receiving portion, to prevent the granular resin from overflowing from the cavity of the lower mold, it is necessary to feed the granular resin into the cavity at an inward offset from the outer contour of the cavity. Therefore, at the start of pressing operation, the resin tends to be insufficient around components located at a peripheral portion of a board. As a result, problems such as incomplete resin filling in gaps under components and void generation become of concern.

As disclosed in PTL 2, the resin material is positioned with a constant thickness inside the raising and lowering member. At the point in time when the resin material and the release film are inserted into the cavity, the resin material is positioned at an inward offset from the outer contour of the cavity by the amount occupied by the raising and lowering member. Therefore, after the raising and lowering member is removed, the resin material tends to be insufficient near the outer contour of the cavity. Thus, at the start of pressing operation, the resin tends to be insufficient around the components located at the peripheral portion of the board. As a result, problems such as incomplete resin filling in gaps under components and void generation become of concern.

The present disclosure is therefore directed to providing an electronic component manufacturing method and manufacturing device capable of reducing or eliminating problems such as incomplete resin filling and void generation caused by insufficient resin around components located at a peripheral portion of a board.

### Solutions to Problems

The electronic component manufacturing method is an electronic component manufacturing method for obtaining an electronic component in which a resin molded body and an object are integrally formed, the manufacturing method including: forming a resin receiving portion by laying a release film on an upper surface of a first support; forming a resin distribution set by feeding a resin material in granular, powder, or liquid form to the resin receiving portion to create a non-uniform distribution, wherein the resin material has a greater thickness at a predetermined location than at other locations; lifting the resin distribution set including the release film and placing the resin distribution set onto a lower mold such that the resin receiving portion is aligned with a cavity provided in the lower mold in a shape corresponding to the resin molded body to form a state in which the resin material is placed above the cavity with the release film interposed therebetween; covering an inner surface of the cavity with the release film and positioning the resin material located in the resin receiving portion into the cavity; and compression-molding the resin material with the object in contact with the resin material located in the cavity to obtain the resin molded body.

### Advantageous Effects

According to the present disclosure, in forming the resin distribution set, the resin material accumulates more thickly at a predetermined location than at other locations, so it is possible to position a larger amount of resin material in an area, such as the peripheral portion of the board, that is prone to problems such as incomplete resin filling and void generation caused by insufficient resin, allowing elimination of these problems when compression molding is performed in the subsequent process.

### BRIEF DESCRIPTION OF DRAWINGS

FIG. 1 is a conceptual diagram of a manufacturing device according to a first embodiment.

FIG. 2 is a flowchart of a manufacturing method according to the first embodiment.

FIG. 3 is a first diagram for describing the manufacturing method according to the first embodiment.

FIG. 4 is a second diagram for describing the manufacturing method according to the first embodiment.

FIG. 5 is a third diagram for describing the manufacturing method according to the first embodiment.

FIG. 6 is a fourth diagram for describing the manufacturing method according to the first embodiment.

FIG. 7 is a fifth diagram for describing the manufacturing method according to the first embodiment.

FIG. 8 is a sixth diagram for describing the manufacturing method according to the first embodiment.

FIG. 9 is a seventh diagram for describing the manufacturing method according to the first embodiment.

FIG. 10 is an eighth diagram for describing the manufacturing method according to the first embodiment.

FIG. 11 is a cross-sectional view of a product obtained through the manufacturing method according to the first embodiment.

FIG. 12 is a first diagram for describing conditions for the manufacturing method according to the first embodiment.

FIG. 13 is a second diagram for describing the conditions for the manufacturing method according to the first embodiment.

FIG. 14 is a conceptual diagram of a manufacturing device according to a second embodiment.

FIG. 15 is a conceptual diagram of a manufacturing device according to a third embodiment.

FIG. 16 is a first diagram for describing a manufacturing method according to the third embodiment.

FIG. 17 is a second diagram for describing the manufacturing method according to the third embodiment.

FIG. 18 is a third diagram for describing the manufacturing method according to the third embodiment.

FIG. 19 is a plan view of a first modification of a plate member applicable to the manufacturing method according to the third embodiment.

FIG. 20 is a cross-sectional view taken along a line XX-XX, as viewed in the direction of arrows in FIG. 19.

FIG. 21 is a cross-sectional view taken along a line XXI-XXI, as viewed in the direction of arrows in FIG. 19.

FIG. 22 is a plan view of a second modification of the plate member applicable to the manufacturing method according to the third embodiment.

FIG. 23 is a plan view of a third modification of the plate member applicable to the manufacturing method according to the third embodiment.

FIG. 24 is a cross-sectional view taken along a line XXIV-XXIV, as viewed in the direction of arrows in FIG. 23.

FIG. 25 is a cross-sectional view taken along a line XXV-XXV, as viewed in the direction of arrows in FIG. 23.

FIG. 26 is a plan view of a fourth modification of the plate member applicable to the manufacturing method according to the third embodiment.

FIG. 27 is a cross-sectional view taken along a line XXVII-XXVII, as viewed in the direction of arrows in FIG. 26.

FIG. 28 is a cross-sectional view taken along a line XXVIII-XXVIII, as viewed in the direction of arrows in FIG. 26.

FIG. 29 is a first diagram for describing a manufacturing method according to a fourth embodiment.

FIG. 30 is a second diagram for describing the manufacturing method according to the fourth embodiment.

FIG. 31 is a third diagram for describing the manufacturing method according to the fourth embodiment.

FIG. 32 is a fourth diagram for describing the manufacturing method according to the fourth embodiment.

FIG. 33 is a fifth diagram for describing the manufacturing method according to the fourth embodiment.

FIG. 34 is a sixth diagram for describing the manufacturing method according to the fourth embodiment.

FIG. 35 is a seventh diagram for describing the manufacturing method according to the fourth embodiment.

FIG. 36 is an eighth diagram for describing the manufacturing method according to the fourth embodiment.

FIG. 37 is a ninth diagram for describing the manufacturing method according to the fourth embodiment.

FIG. 38 is a first diagram for describing a manufacturing method according to a fifth embodiment.

FIG. 39 is a second diagram for describing the manufacturing method according to the fifth embodiment.

FIG. 40 is a third diagram for describing the manufacturing method according to the fifth embodiment.

FIG. 41 is a fourth diagram for describing the manufacturing method according to the fifth embodiment.

FIG. 42 is a fifth diagram for describing the manufacturing method according to the fifth embodiment.

FIG. 43 is a sixth diagram for describing the manufacturing method according to the fifth embodiment.

FIG. 44 is a first diagram for describing a manufacturing method according to a sixth embodiment.

FIG. 45 is a second diagram for describing the manufacturing method according to the sixth embodiment.

FIG. 46 is a third diagram for describing the manufacturing method according to the sixth embodiment.

FIG. 47 is a fourth diagram for describing the manufacturing method according to the sixth embodiment.

FIG. 48 is a fifth diagram for describing the manufacturing method according to the sixth embodiment.

### DESCRIPTION OF EMBODIMENTS

The dimensional ratios illustrated in the drawings do not necessarily represent the actual dimensional ratios, and the dimensional ratios may be exaggerated for convenience of description. In the following description, when referring to a superordinate or subordinate concept, it does not necessarily mean an absolute superordinate or subordinate, but may mean a relative superordinate or subordinate in the illustrated modes.

### First Embodiment

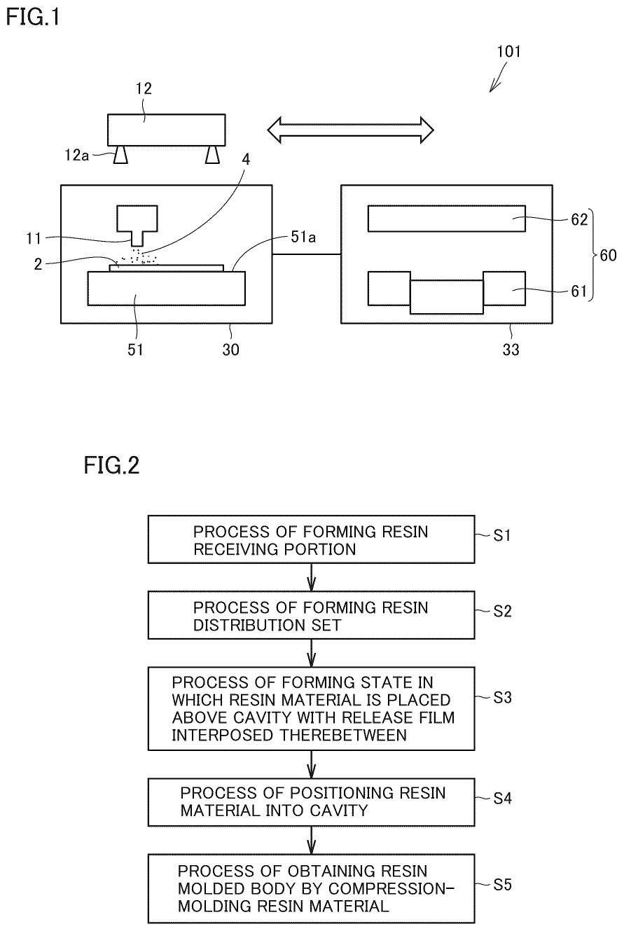

With reference to FIGS. 1 to 11, an electronic component manufacturing method and manufacturing device according to a first embodiment will be described.

FIG. 1 illustrates a manufacturing device 101 according to the present embodiment. FIG. 1 is merely a conceptual representation of manufacturing device 101, and the shapes and configurations of the components are not necessarily limited to those illustrated in the drawing. FIG. 2 is a flowchart of the electronic component manufacturing method according to the present embodiment.

As illustrated in FIG. 1, manufacturing device 101 includes a resin distribution set forming device 30, a compression molding device 33, and a conveying device 12. Resin distribution set forming device 30 includes a first support 51 and a feeding device 11 that feeds a resin material 4 onto a release film 2 laid on an upper surface of first support 51. Resin material 4 may be in granular, powder, or liquid form. Resin material 4 descends from feeding device 11 under gravity. Conveying device 12 includes a suction nozzle 12a. Conveying device 12 can move back and forth between resin distribution set forming device 30 and compression molding device 33. Compression molding device 33 includes a mold 60. Mold 60 includes an upper mold 62 and a lower mold 61.

Note that release film 2 and resin material 4 are not a part of manufacturing device 101. In FIG. 1, release film 2 and resin material 4 are also illustrated for convenience of description.

Each process performed by manufacturing device 101 will be sequentially described.

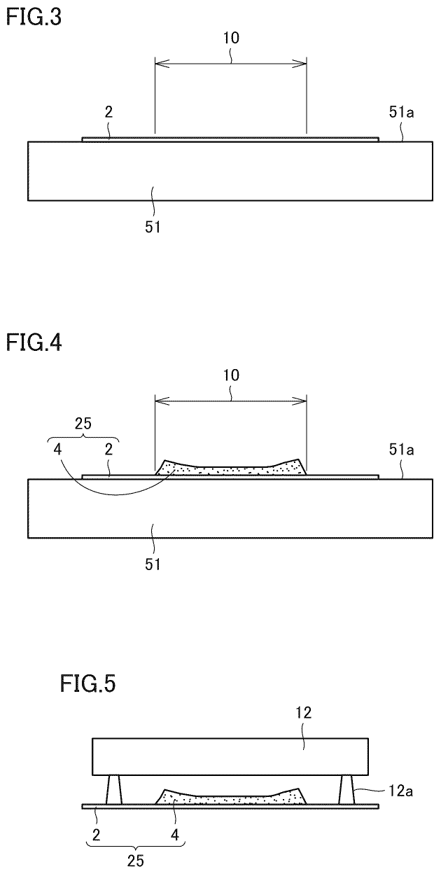

First, as process S1, as illustrated in FIG. 3, release film 2 is laid on an upper surface 51a of first support 51. A resin receiving portion 10 is formed by laying release film 2. In the example illustrated in FIG. 4, the resin receiving portion 10 is an unenclosed region, i.e., not surrounded by any member; defined on the upper surface of release film 2 serves as resin receiving portion 10. As will be described later in another embodiment, any member may surround a certain region on the upper surface of release film 2 to form resin receiving portion 10. In other embodiments, as will be described later, the resin receiving portion 10 may be defined by a physical boundary, such as a frame member.

Next, as process S2, as illustrated in FIG. 4, resin material 4 is placed within resin receiving portion 10 defined on the upper surface of release film 2. As a result, a resin distribution set 25 is formed. Resin distribution set 25 includes release film 2 and resin material 4. However, the resin material 4 is placed with a non-uniform distribution, such that the resin material 4 accumulates more thickly at a predetermined location, e.g., a desired location, than at other locations. In the example illustrated in FIG. 4, resin material 4 accumulates less thickly in the middle in a left-right direction and accumulates more thickly near both ends in the left-right direction.

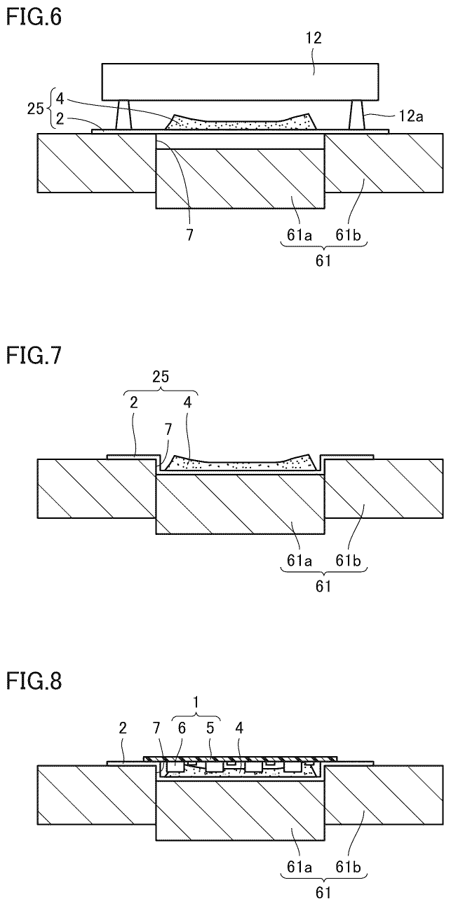

Process S3 is performed. In process S3, first, as illustrated in FIG. 5, conveying device 12 lifts resin distribution set 25. Conveying device 12 can lift resin distribution set 25 in its original form by sucking release film 2 with suction nozzle 12a. Thereafter, as illustrated in FIG. 6, conveying device 12 places resin distribution set 25 onto lower mold 61. Lower mold 61 is provided in advance with a cavity 7 having a shape corresponding to that of a resin molded body to be formed. Conveying device 12 places resin distribution set 25 onto lower mold 61 such that resin receiving portion 10 is aligned with cavity 7. By doing so, a state in which resin material 4 is placed above cavity 7 with release film 2 interposed therebetween is formed. In the example illustrated here, lower mold 61 includes a lower mold first portion 61a and a lower mold second portion 61b. Lower mold first portion 61a is vertically displaceable relative to lower mold second portion 61b. By vertically displacing lower mold first portion 61a relative to lower mold second portion 61b, the depth of cavity 7 can be varied. As will be described in detail later, by varying the depth of cavity 7 in this manner, mold 60 can apply pressure to resin material 4 in cavity 7.

Process S4 is performed. That is, as illustrated in FIG. 7, a release film 2 covers an inner surface of cavity 7, and resin material 4 in the resin receiving portion 10 is positioned in the cavity 7. For example, upon release of the conveying device 12, e.g., by deactivating a suction nozzle 12a, a central portion of the resin distribution set 25 sags into the cavity 7 by gravity, causing the release film 2 to conform to the inner surface of the cavity 7 as illustrated in FIG. 7. In practice, the central portion of resin distribution set 25 may sag into cavity 7 even immediately after the placement as illustrated in FIG. 6 and before conveying device 12 stops suction. The phenomenon where the central portion of resin distribution set 25 sags into cavity 7 is not limited to sagging due to natural fall under gravity, and may be caused by, for example, actively pushing the central portion downward with some member as described later in another embodiment.

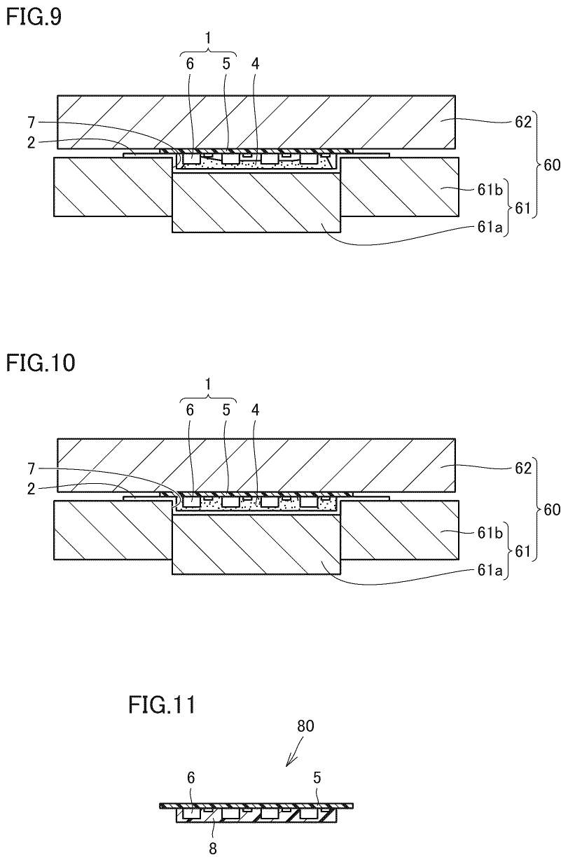

Process S5 is performed. For this purpose, first, as illustrated in FIG. 8, an object 1 is placed onto cavity 7. In the example illustrated here, object 1 includes a board 5 and a component 6 mounted on one surface of board 5. In FIG. 8, object 1 is placed onto cavity 7 with the surface on which component 6 is mounted facing downward. In cavity 7, object 1 is in contact with resin material 4. Outside cavity 7, board 5 is in contact with lower mold 61 with release film 2 interposed therebetween. Next, as illustrated in FIG. 9, upper mold 62 is brought into contact with the upper side of object 1. Here, after object 1 is placed, upper mold 62 is brought into contact with the upper side of object 1, but as another method, for example, object 1 may be placed onto cavity 7 by bringing upper mold 62 holding object 1 close.

In the state illustrated in FIG. 9, heat and pressure are applied between upper mold 62 and lower mold 61. In the example illustrated here, as illustrated in FIG. 10, by raising lower mold first portion 61a, the depth of cavity 7 is reduced. As described above, by reducing the volume of cavity 7, pressure is applied. As a result, resin material 4 conforms to the shape of object 1 in cavity 7 and fills gaps. Due to the applied heat, resin material 4 melts in this state.

By doing so, resin material 4 melts and then solidifies into a shape that conforms to cavity 7. After separating upper mold 62 and lower mold 61, the product is taken out. As a result, an electronic component 80 illustrated in FIG. 11 is obtained. The above constitutes process S5. In the example illustrated in FIG. 11, a plurality of components 6 are mounted on one surface of board 5 and are encapsulated in a resin molded body 8. Resin material 4 melts and then solidifies to form resin molded body 8. In the electronic component 80, the plurality of components 6 are covered by the resin molded body 8 formed using the manufacturing method noted above that is substantially free of voids at the periphery. This lack of voids may arise from an increased thickness of resin material provided to the periphery and/or an increased density at the periphery, as discussed in detail below.

Here, the electronic component manufacturing method according to the present embodiment can be expressed as follows. The electronic component manufacturing method according to the present embodiment is an electronic component manufacturing method for obtaining electronic component 80 in which resin molded body 8 and object 1 are integrally formed, the manufacturing method including: process S1 of forming resin receiving portion 10 by laying release film 2 on upper surface 51a of first support 51; process S2 of forming resin distribution set 25 in which resin material 4 in granular, powder, or liquid form accumulates more thickly at a desired location than at other locations by feeding resin material 4 to resin receiving portion 10; process S3 of lifting resin distribution set 25 including release film 2 and placing resin distribution set 25 onto lower mold 61 such that resin receiving portion 10 is aligned with cavity 7 provided in lower mold 61 in a shape corresponding to resin molded body 8 to form a state in which resin material 4 is placed above cavity 7 with release film 2 interposed therebetween; process S4 of covering an inner surface of cavity 7 with release film 2 and positioning resin material 4 located in resin receiving portion 10 into cavity 7; and process S5 of compression-molding resin material 4 with object 1 in contact with resin material 4 located in cavity 7 to obtain resin molded body 8.

On the other hand, the electronic component manufacturing device according to the present embodiment can be expressed as follows.

Electronic component manufacturing device 101 according to the present embodiment is an electronic component manufacturing device for obtaining electronic component 80 in which resin molded body 8 and object 1 are integrally formed, the manufacturing device including: resin distribution set forming device 30 that forms resin distribution set 25 in which resin material 4 in granular, powder, or liquid form accumulates more thickly at a desired location than at other locations by feeding resin material 4 to resin receiving portion 10 formed on release film 2; conveying device 12 that lifts resin distribution set 25 including release film 2 and places resin distribution set 25 onto lower mold 61 such that resin receiving portion 10 is aligned with cavity 7 provided in lower mold 61 in a shape corresponding to resin molded body 8; and compression molding device 33 that compression-molds resin material 4 with object 1 in contact with resin material 4 located in cavity 7. However, when conveying device 12 places resin distribution set 25 onto lower mold 61, the inner surface of cavity 7 is covered with release film 2, and resin material 4 located in resin receiving portion 10 is positioned into cavity 7.

In the present embodiment, in forming resin distribution set 25 in process S2, resin material 4 accumulates more thickly at a desired location than at other locations, so it is possible to position a larger amount of resin material 4 in an area, such as the peripheral portion of the board, that is prone to problems such as incomplete resin filling and void generation caused by insufficient resin, allowing reduction or elimination of these problems when compression molding is performed in subsequent process S5.

Note that, when implementing the electronic component manufacturing method according to the present embodiment, in resin distribution set 25, resin material 4 may accumulate more thickly at a near-peripheral portion of resin receiving portion 10 than at a central portion. As a configuration of the electronic component manufacturing device according to the present embodiment, the resin distribution set forming device may form resin distribution set 25 such that resin material 4 accumulate more thickly at the near-peripheral portion of resin receiving portion 10 than at the central portion. By doing so, problems such as incomplete resin filling and void generation caused by insufficient resin at the near-peripheral portion, i.e., near the components located at the peripheral portion of the board of the object may be more effectively and accurately reduced or eliminated.

In particular, making the deposition thickness of resin material 4 at the peripheral portion greater is suitable for reducing or eliminating insufficient resin material at the peripheral portion of the board, particularly at the four corners, at the start of pressing when compression molding is performed in process S5. Furthermore, by doing so, it can also help prevent defects such as tearing and wrinkling of release film 2 that may occur due to insufficient resin material. By pre-positioning a greater amount of resin in predetermined areas, e.g., critical areas, this method ensures complete encapsulation and reduces or eliminates molding defect.

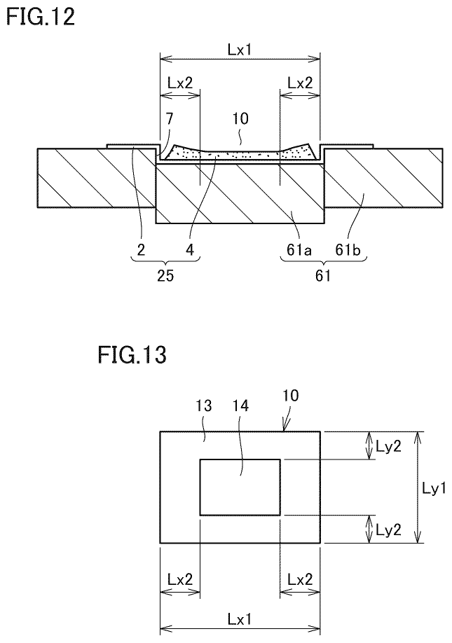

Conditions for the deposition thickness of resin material 4 will be described in more detail in FIGS. 12 and 13. As illustrated in FIG. 12, a length of the resin receiving portion in an X direction is defined as Lx1. A length of the near-peripheral portion in the X direction is defined as Lx2. As viewed from above, this configuration is as illustrated in FIG. 13. A near-peripheral portion 13 surrounds a central portion 14. FIG. 13 illustrates only the inside of resin receiving portion 10. Lx1 denotes the length of resin receiving portion 10 in the X direction. Ly1 denotes a length of resin receiving portion 10 in a Y direction. Lx2 denotes a width of near-peripheral portion 13 in the X direction. Ly2 denotes a width of near-peripheral portion 13 in the Y direction. At central portion 14, resin material 4 is positioned with a constant thickness. As illustrated in FIG. 12, at near-peripheral portion 13, the thickness of resin material 4 need not be constant and may be zero in an area extremely near the periphery of resin receiving portion 10. On the other hand, resin material 4 may be thicker in an area somewhat away from the periphery than at central portion 14. That is, in some areas of near-peripheral portion 13, resin material 4 may be locally thicker than at central portion 14.

An average thickness of resin material 4 at near-peripheral portion 13 is greater than or equal to 0.8 times the thickness of resin material 4 at central portion 14. The average thickness of resin material 4 at near-peripheral portion 13 may be greater than the thickness of resin material 4 at central portion 14. In the examples illustrated in FIGS. 12 and 13, Lx2 is less than or equal to 25% of Lx1. Ly2 is less than or equal to 25% of Ly1.

Although the thickness has been mentioned here, a similar relationship may hold for a weight per unit area instead of the thickness. That is, resin material 4 may be positioned such that a weight per unit area of resin material 4 at near-peripheral portion 13 is greater than or equal to 0.8 times a weight per unit area of resin material 4 at central portion 14. When resin material 4 has a constant density, the thickness and the weight per unit area have a proportional relationship; therefore, when the thickness is greater than or equal to 0.8 times, the weight per unit area naturally becomes greater than or equal to 0.8 times, but, in a case where resin materials 4 with different particle sizes are used in combination, the density differs, and thus the thickness and the weight per unit area do not necessarily have a proportional relationship. The smaller the particle size of resin material 4, the fewer the gaps, and the higher the density. For example, when a resin material with a small particle size is positioned at near-peripheral portion 13 to increase the density, even if the thickness is less than 0.8 times the thickness at central portion 14, the resin material can be positioned such that the weight per unit area is greater than or equal to 0.8 times.

As described here, the resin material 4 may be positioned at central portion 14 to have either a constant thickness or a constant weight per unit area, near-peripheral portion 13 include a portion where resin material 4 is positioned with a greater thickness than at central portion 14 and a portion where resin material 4 is positioned with a smaller thickness than at central portion 14, the average thickness or the weight per unit area of resin material 4 at near-peripheral portion 13 be greater than or equal to 0.8 times the thickness or the weight per unit area of resin material 4 at central portion 14, and the widths of near-peripheral portion 13 in the X and Y directions be less than or equal to 25% of the lengths of resin receiving portion 10 in the X and Y directions, respectively, as viewed from above. By employing this configuration, it becomes easier to form a resin distribution set with a desired shape. In particular, in a case where a manufacturing method including a process of spreading the distribution of the resin material by vibration is employed, it becomes easier to form a resin distribution set with a desired shape by positioning resin material 4 to satisfy the conditions described here and then applying vibration.

### Second Embodiment

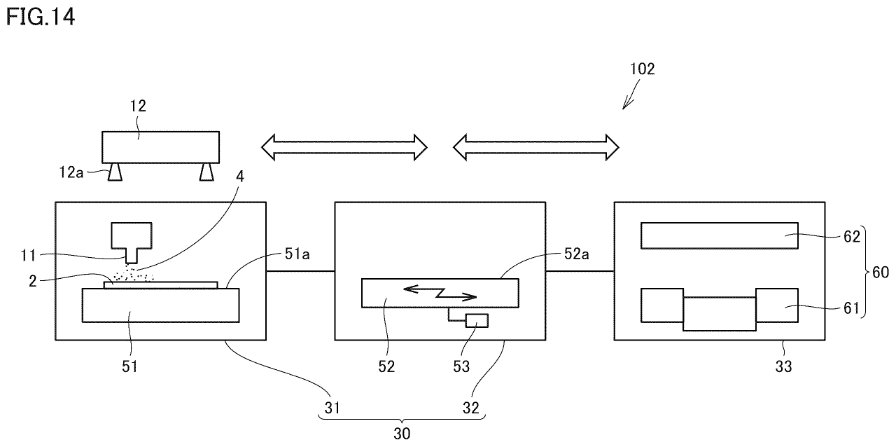

With reference to FIG. 14, an electronic component manufacturing method and manufacturing device according to a second embodiment will be described. Descriptions repetitive of those in the first embodiment will not be repeated.

FIG. 14 illustrates a manufacturing device 102 according to the present embodiment. In manufacturing device 102, resin distribution set forming device 30 includes a first portion 31 and a second portion 32. Conveying device 12 can move back and forth between first portion 31 and compression molding device 33 and between second portion 32 and compression molding device 33. First portion 31 includes first support 51 and feeding device 11. Second portion 32 includes a second support 52 and a vibration applying device 53. Second support 52 has an upper surface 52a. Vibration applying device 53 may be, for example, a piston vibrator. Through the operation of vibration applying device 53, second support 52 is able to vibrate. The vibration generated in second support 52 may be vibration in either a horizontal direction, that is, the X direction or the Y direction, or may be vibration in a vertical direction, that is, a Z direction. To level granular resin materials 4 with various particle sizes, the appropriate frequency ranges, for example, from 50 Hz to 300 Hz.

In the electronic component manufacturing method according to the present embodiment, process S2 of forming resin distribution set 25 includes a process of feeding resin material 4 into resin receiving portion 10, and a process of spreading the distribution of resin material 4 by vibrating second support 52 with resin receiving portion 10 placed on upper surface 52a of second support 52.

In electronic component manufacturing device 102 according to the present embodiment, resin distribution set forming device 30 includes: first support 51 on which release film 2 is placed to form resin receiving portion 10; feeding device 11 that feeds resin material 4 into resin receiving portion 10; and second support 52 having upper surface 52a, and second support 52 is vibrated with resin receiving portion 10 placed on upper surface 52a to spread the distribution of resin material 4.

In the present embodiment, since the distribution of resin material 4 is spread by vibrating second support 52, the distribution of resin material 4 can be spread to a desired state. It is therefore possible to position a sufficient amount of resin material 4 in an area, such as the peripheral portion of the board, prone to problems such as incomplete resin filling and void generation caused by insufficient resin, allowing reduction or elimination of these problems when compression molding is performed in subsequent process S5.

Note that upper surface 52a of second support 52 may be flat as in manufacturing device 102; alternatively, upper surface 52a may include a locally raised portion as described below.

### Third Embodiment

With reference to FIGS. 15 to 18, an electronic component manufacturing method and manufacturing device according to a third embodiment will be described. Descriptions repetitive of those in the above-described embodiments will not be repeated.

FIG. 15 illustrates an electronic component manufacturing device 103 according to the third embodiment. In manufacturing device 103, by installing a plate member 54 on a flat upper surface of a support, a locally raised portion is formed on upper surface 52a of second support 52. Plate member 54 is a part of second support 52. In the portion raised by plate member 54, an upper surface of plate member 54 serves as upper surface 52a of second support 52.

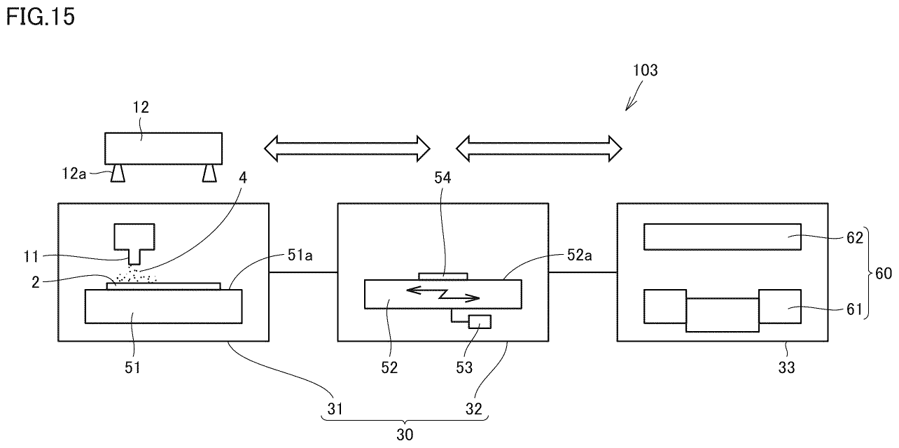

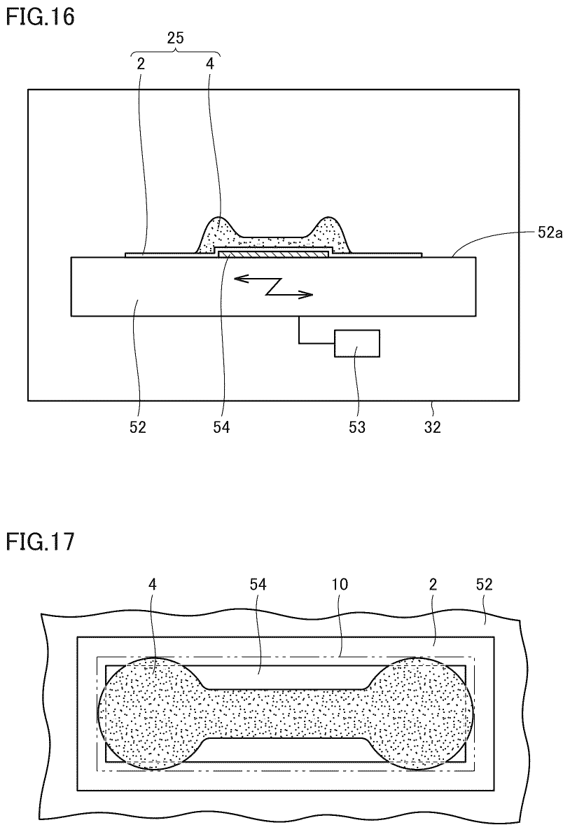

In the electronic component manufacturing method according to the third embodiment, in a process of using second support 52 in process S2, as illustrated in FIG. 16, resin material 4 is positioned so as to extend across the region raised by plate member 54. In this state, the distribution of resin material 4 is spread by vibrating second support 52.

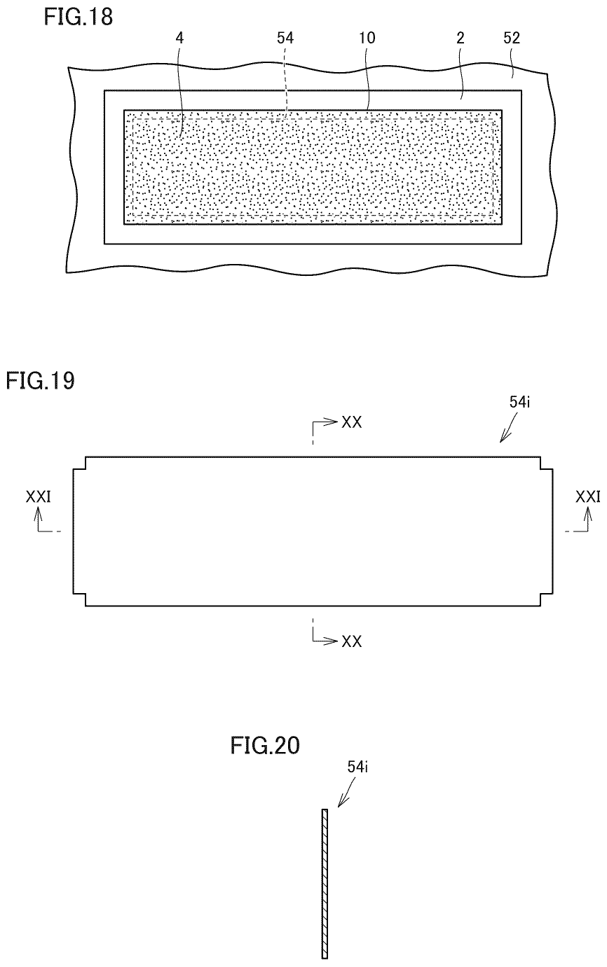

As viewed from directly above, resin material 4 is positioned as illustrated in FIG. 17 at the point in time before the start of vibration of second support 52. That is, resin receiving portion 10 has a rectangular shape, and a portion where resin material 4 accumulates more thickly is present near both ends in a longitudinal direction. At the middle portion in the longitudinal direction, resin material 4 is positioned in a linear pattern. That is, a portion where resin material 4 accumulates less thickly extends linearly. Vibrating second support 52 for a certain period of time results in the state as illustrated in FIG. 18. That is, resin material 4 is distributed throughout resin receiving portion 10. However, even in the state illustrated in FIG. 18, resin material 4 is not positioned with a uniform thickness throughout resin receiving portion 10. Resin receiving portion 10 includes a section where the deposition thickness of resin material 4 is greater and a section where the deposition thickness of resin material 4 is smaller.

In the electronic component manufacturing method according to the present embodiment, a section of upper surface 52a of second support 52 corresponding to the center of resin receiving portion 10 is higher than other sections.

In electronic component manufacturing device 103 according to the present embodiment, the section of upper surface 52a of second support 52 corresponding to the center of resin receiving portion 10 is higher than the other sections.

In the present embodiment, since the section of upper surface 52a of second support 52 corresponding to the center of resin receiving portion 10 is higher than the other sections, resin material 4 located in this section can be distributed to the other sections. Since vibrating second support 52 causes resin material 4 to move to a lower level, the deposition thickness of resin material 4 decreases in a section where upper surface 52a is locally raised, and resin material 4 is deposited more thickly in the other sections. By doing so, it becomes easier to set the distribution of resin material 4 to a desired state. The difference in height provided on upper surface 52a of second support 52 is merely present on upper surface 52a of second support 52, and in process S3, resin distribution set 25 is lifted and separated from upper surface 52a. As a result, the difference in the deposition thickness of resin material 4 is maintained in resin distribution set 25.

The deposition thickness of resin material 4 is smaller in a section where plate member 54 is present, and the deposition thickness of resin material 4 is greater in a section where plate member 54 is not present. The planar shape of plate member 54 is not limited to a rectangular shape, and may be another shape. The thickness of plate member 54 is not necessarily uniform and may vary. Some modifications of the plate member will be described below.

### (First Modification of Plate Member)

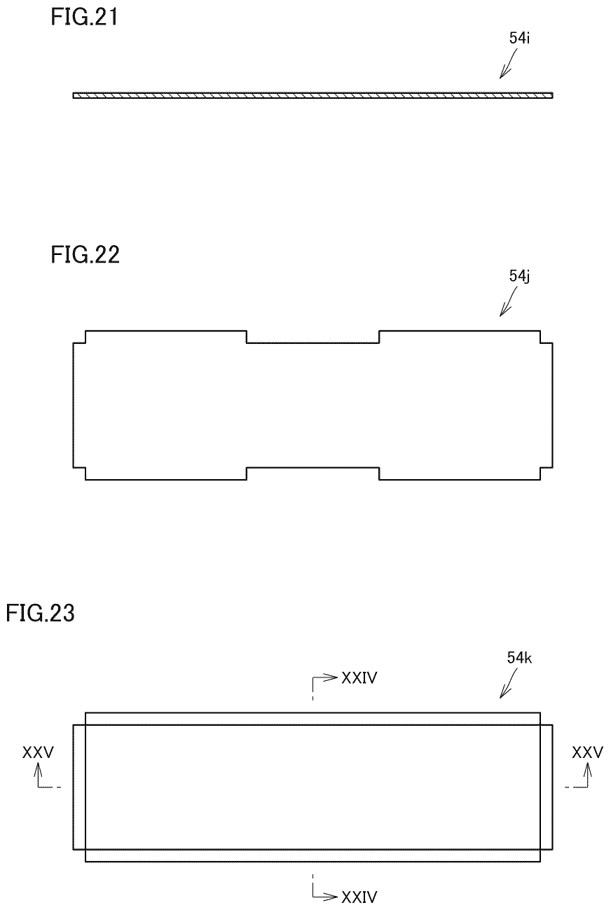

As a first modification of the plate member, a plate member 54i illustrated in FIG. 19 can be considered. FIG. 20 is a cross-sectional view taken along a line XX-XX, as viewed in the direction of arrows in FIG. 19. FIG. 21 is a cross-sectional view taken along a line XXI-XXI, as viewed in the direction of arrows in FIG. 19. Plate member 54i has a constant thickness and has notches at the four corners.

### (Second Modification of Plate Member)

As a second modification of the plate member, a plate member 54j illustrated in FIG. 22 can be considered. Plate member 54j has a constant thickness, and has not only notches at the four corners, but also a narrower section in the middle. That is, plate member 54j has a narrow portion in the middle.

### (Third Modification of Plate Member)

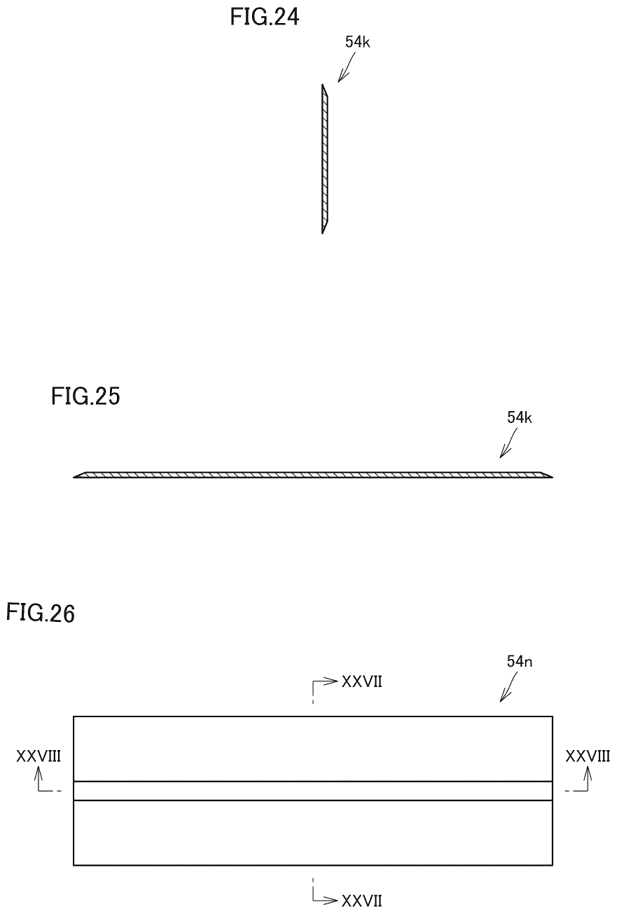

As a third modification of the plate member, a plate member 54k illustrated in FIG. 23 can be considered. FIG. 24 is a cross-sectional view taken along a line XXIV-XXIV, as viewed in the direction of arrows in FIG. 23. FIG. 25 is a cross-sectional view taken along a line XXV-XXV, as viewed in the direction of arrows in FIG. 23. Plate member 54k has notches at the four corners, and further has a bevel on each of the four sides. The bevel provided on each side is approximately equal in length to one side of the notch provided at each of the four corners. The thickness of the bevel provided on each side decreases toward the end.

### (Fourth Modification of Plate Member)

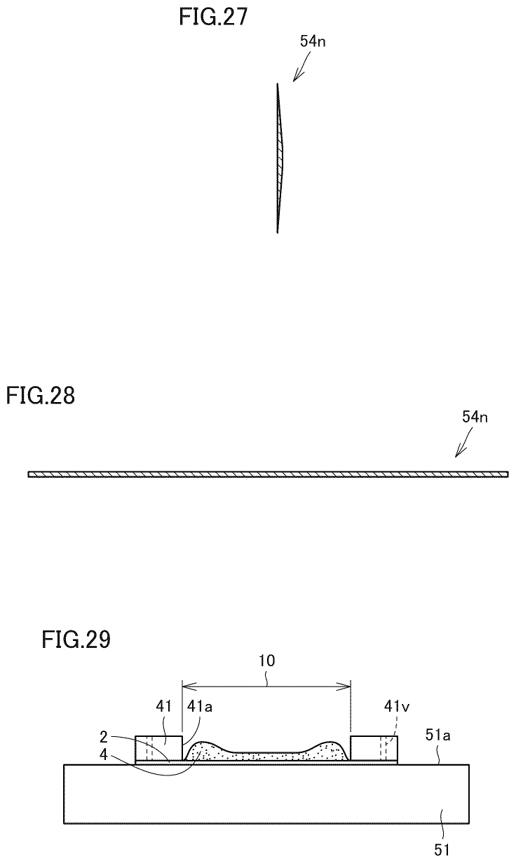

As a fourth modification of the plate member, a plate member 54n illustrated in FIG. 26 can be considered. FIG. 27 is a cross-sectional view taken along a line XXVII-XXVII, as viewed in the direction of arrows in FIG. 26. FIG. 28 is a cross-sectional view taken along a line XXVIII-XXVIII, as viewed in the direction of arrows in FIG. 26. Plate member 54n has a bevel extending along two opposing long sides. A band-shaped flat region having a constant width is provided from one end to the other end along the center line in the longitudinal direction. The bevel provided on each long side connects to the band-shaped flat region. As viewed from above, an area occupied by the bevel region is greater than an area occupied by the band-shaped flat region within the overall structure.

### Fourth Embodiment

With reference to FIGS. 29 to 37, an electronic component manufacturing method and manufacturing device according to a fourth embodiment will be described. Descriptions repetitive of those in the above-described embodiments will not be repeated.

In the electronic component manufacturing method according to the present embodiment, process S1 of forming resin receiving portion 10 includes a process of positioning a first frame member 41 with a first through hole 41a corresponding to the shape of cavity 7 on release film 2 as illustrated in FIG. 29. First through hole 41a serves as resin receiving portion 10. First frame member 41 has a suction hole 41v.

In the electronic component manufacturing device according to the present embodiment, resin distribution set forming device 30 includes first frame member 41 that is positioned on release film 2. First frame member 41 has first through hole 41a corresponding to the shape of cavity 7. First through hole 41a serves as resin receiving portion 10.

Process S2 of forming resin distribution set 25 according to the present embodiment will be described. In process S2, first, release film 2, resin material 4, and first frame member 41 are collectively lifted by conveying device 12. Conveying device 12 can suck first frame member 41, and can further suck release film 2 through suction hole 41v provided in first frame member 41. Therefore, conveying device 12 can collectively lift release film 2, resin material 4, and first frame member 41 while maintaining their positional relationship.

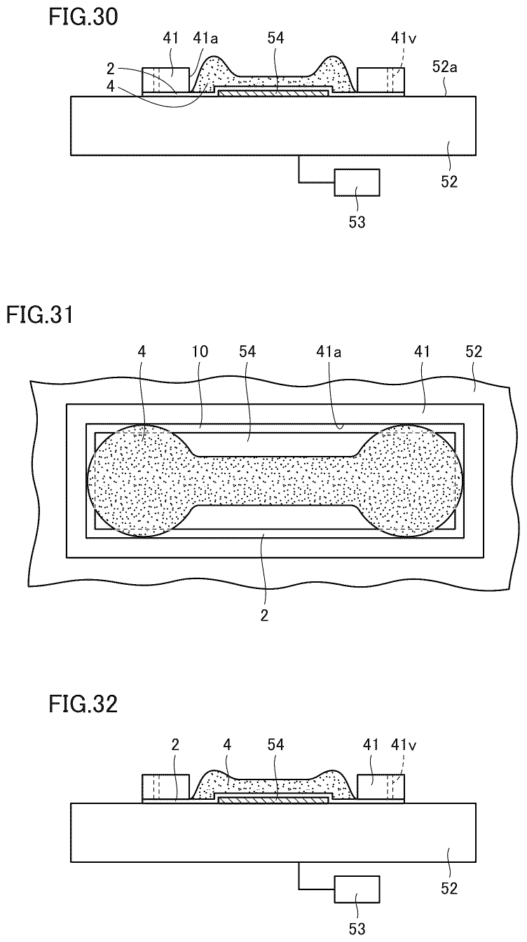

As illustrated in FIG. 30, release film 2, resin material 4, and first frame member 41 are collectively placed onto second support 52 by conveying device 12. Second support 52 includes plate member 54. The central portion of upper surface 52a is raised due to the presence of plate member 54. Vibration applying device 53 is connected to second support 52.

FIG. 31 is a plan view of this state. This is a state before the start of vibration of second support 52. Resin material 4 is positioned within resin receiving portion 10 defined by first through hole 41a of first frame member 41. However, at this point in time, resin receiving portion 10 is not entirely covered with resin material 4, and there is also a region where release film 2 or plate member 54 is exposed. FIG. 32 illustrates a cross-sectional view of the state illustrated in FIG. 31.

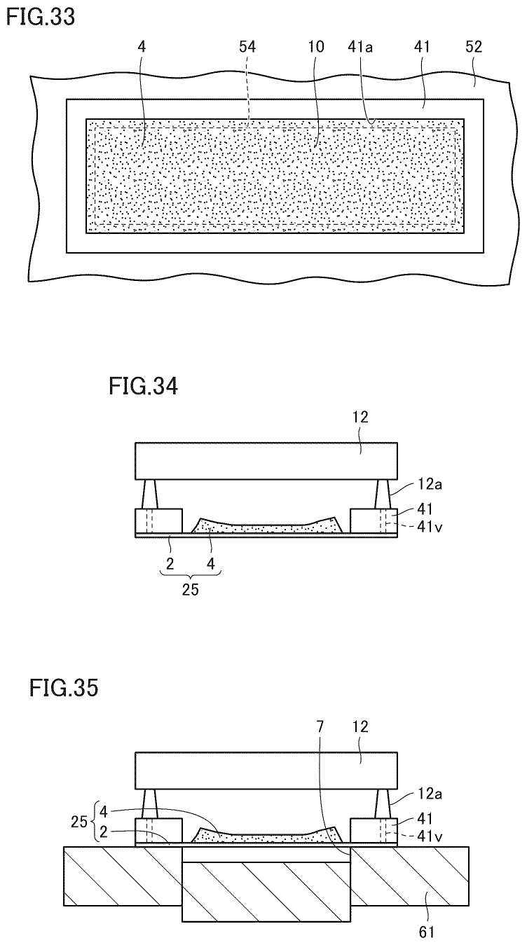

Vibrating second support 52 using vibration applying device 53 for a certain period of time results in the state as illustrated in FIG. 33. That is, resin material 4 is distributed throughout resin receiving portion 10. In the present embodiment, since resin receiving portion 10 corresponds to the entire internal region of first through hole 41a, resin material 4 is distributed throughout the entire internal region of first through hole 41a. However, even at this point in time, the deposition thickness of resin material 4 is not uniform. Resin receiving portion 10 includes a section where the deposition thickness of resin material 4 is greater and a section where the deposition thickness of resin material 4 is smaller. At this point in time, the combination of resin material 4 and release film 2 corresponds to resin distribution set 25. The above constitutes process S2 of forming resin distribution set 25.

Next, process S3 will be described. In process S3, first, as illustrated in FIG. 34, resin distribution set 25 and first frame member 41 are collectively lifted by conveying device 12. Suction nozzle 12a of conveying device 12 is illustrated in a simplified manner in FIG. 34, but in practice, a plurality of suction nozzles 12a are arranged in a front-to-back direction of the drawing. The plurality of suction nozzles 12a include suction nozzles that suck the upper surface of first frame member 41 and suction nozzles that suck release film 2 through suction hole 41v of first frame member 41. Next, as illustrated in FIG. 35, conveying device 12 places resin distribution set 25 onto lower mold 61. The above constitutes process S3.

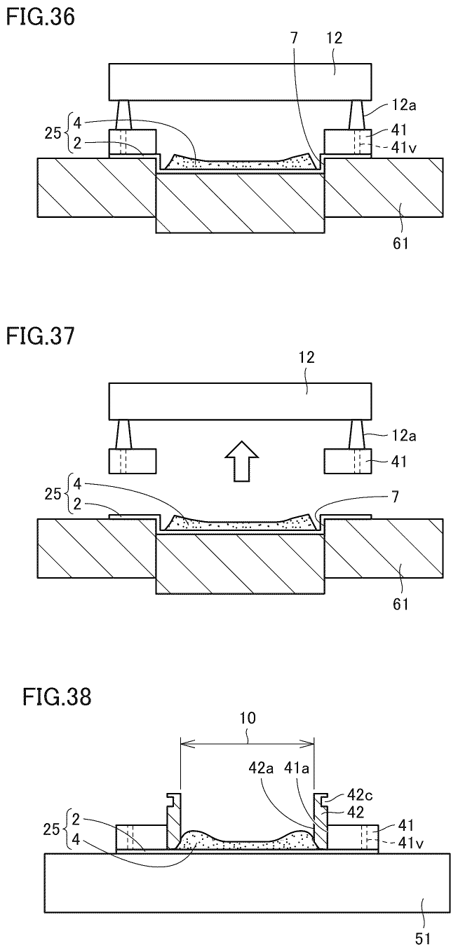

Process S4 is performed. As illustrated in FIG. 36, release film 2 covers the inner surface of cavity 7, and resin material 4, which is located in resin receiving portion 10, is positioned within cavity 7. For example, when suction nozzle 12a of conveying device 12 stops the suction performed on release film 2 through suction hole 41v, the central portion of resin distribution set 25 sags into cavity 7 under gravity, resulting in the state illustrated in FIG. 36. The above constitutes process S4.

As illustrated in FIG. 37, conveying device 12 lifts first frame member 41 by suction. In this state, suction nozzle 12a of conveying device 12 does not suck release film 2 but only sucks first frame member 41.

Thereafter, process S5 of compression-molding resin material 4 to obtain resin molded body 8 is performed. Process S5 is performed in the same manner as that described in the first embodiment with reference to FIGS. 8 to 11.

In the present embodiment, since resin receiving portion 10 is defined using first through hole 41a of first frame member 41, it is possible to prevent resin material 4 from protruding from resin receiving portion 10, and it becomes easier to achieve a desired distribution of resin material 4 within resin receiving portion 10.

Note that, in the present embodiment, the example including the process of applying vibration using second support 52 to spread the distribution of resin material 4 has been described, but the configuration including second support 52 and the process of vibrating second support 52 are not essential.

### Fifth Embodiment

With reference to FIGS. 38 to 43, an electronic component manufacturing method and manufacturing device according to a fifth embodiment will be described. Descriptions repetitive of those in the above-described embodiments will not be repeated.

In the electronic component manufacturing method according to the present embodiment, process S1 of forming resin receiving portion 10 includes a process of positioning first frame member 41 and a second frame member 42 on release film 2 as illustrated in FIG. 38. First frame member 41 has first through hole 41a corresponding to the shape of cavity 7. Second frame member 42 is positioned within first through hole 41a. Second frame member 42 has a second through hole 42a. Second through hole 42a serves as resin receiving portion 10. Process S4 of positioning resin material 4 within cavity 7 includes a process of pushing release film 2 into cavity 7 by lowering second frame member 42 relative to first frame member 41. Second frame member 42 has a recess 42c.

In the electronic component manufacturing device according to the present embodiment, resin distribution set forming device 30 includes first frame member 41 and second frame member 42 that are positioned on release film 2. First frame member 41 has first through hole 41a corresponding to the shape of cavity 7. Second frame member 42 is positioned within first through hole 41a. Second frame member 42 has second through hole 42a. Second through hole 42a serves as resin receiving portion 10. This manufacturing device includes a mechanism that pushes release film 2 into cavity 7 by lowering second frame member 42 relative to first frame member 41.

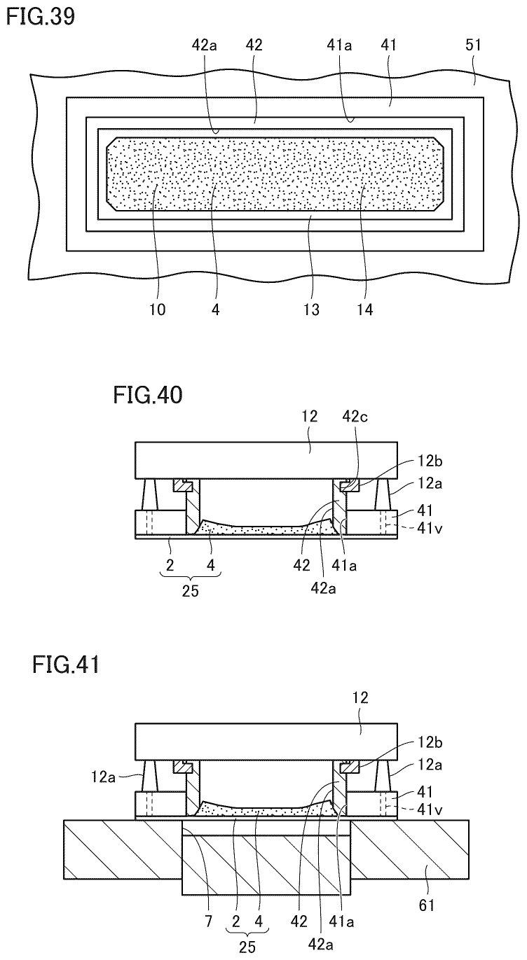

In the present embodiment, in process S2 of forming resin distribution set 25, the state illustrated in FIG. 38 is obtained, and FIG. 39 is a plan view of the state. Resin receiving portion 10 includes near-peripheral portion 13 and the central portion. Near-peripheral portion 13 is a portion located immediately inside second frame member 42 and is a frame-shaped region. The central portion is a portion surrounded by near-peripheral portion 13. The deposition thickness of resin material 4 at near-peripheral portion 13 is greater than at the central portion.

This may be transferred onto second support 52 and vibrated to spread the distribution of resin material 4. Resin distribution set 25 is formed, regardless of the presence or absence of the process of transferring onto second support 52 and applying vibration.

Next, process S3 will be described. In process S3, first, as illustrated in FIG. 40, resin distribution set 25, first frame member 41, and second frame member 42 are lifted by conveying device 12. In the present embodiment, conveying device 12 includes a hook 12b. Hook 12b is displaceable in the horizontal direction and the vertical direction. Engaging the tip of hook 12b with recess 42c of second frame member 42 enables conveying device 12 to lift second frame member 42. Next, as illustrated in FIG. 41, resin distribution set 25, first frame member 41, and second frame member 42 are placed onto lower mold 61 by conveying device 12. The above constitutes process S3.

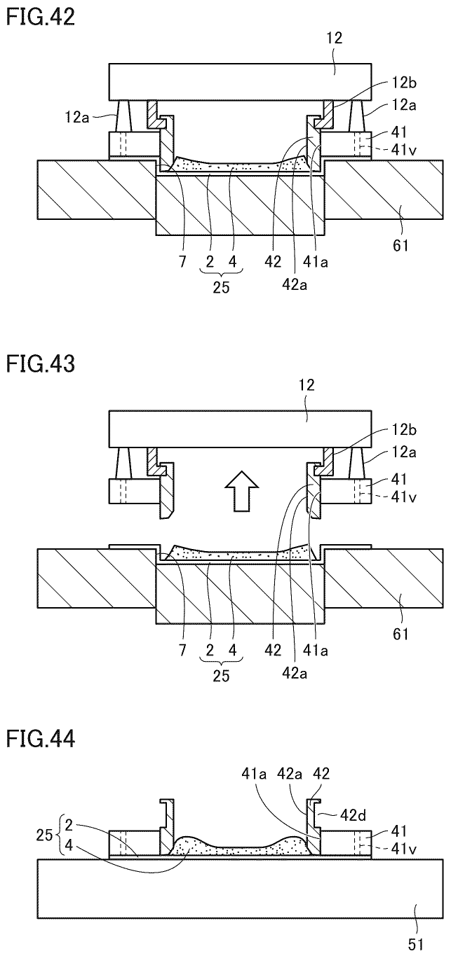

Process S4 is performed. As illustrated in FIG. 42, release film 2 covers the inner surface of cavity 7, and resin material 4, which is located in resin receiving portion 10, is positioned within cavity 7. For this purpose, first, the suction of release film 2 by suction nozzle 12a of conveying device 12 is stopped. Then, hook 12b is lowered. Since hook 12b is engaged with second frame member 42, second frame member 42 is pushed downward as illustrated in FIG. 42. Second frame member 42 is pushed downward, whereas first frame member 41 is not. This enables only second frame member 42 to move in the vertical direction without moving first frame member 41. The central portion of resin distribution set 25 sags into cavity 7 under gravity, resulting in the state illustrated in FIG. 42.

As illustrated in FIG. 43, conveying device 12 moves upward. The suction of first frame member 41 by suction nozzle 12a continues. First frame member 41 and second frame member 42 are lifted by conveying device 12. When the central portion of resin distribution set 25 sinks into cavity 7 of lower mold 61, resin material 4 is positioned within cavity 7. The above constitutes process S4.

Thereafter, process S5 of compression-molding resin material 4 to obtain resin molded body 8 is performed. Process S5 is performed in the same manner as that described in the first embodiment with reference to FIGS. 8 to 11.

In the present embodiment, since the central portion of resin distribution set 25 is pushed into cavity 7 using second frame member 42, resin material 4 can be positioned in a desired location with high reliability.

### Sixth Embodiment

With reference to FIGS. 44 to 48, an electronic component manufacturing method and manufacturing device according to a sixth embodiment will be described. Descriptions repetitive of those in the above-described embodiments will not be repeated.

In the present embodiment, in process S2 of forming resin distribution set 25, the state illustrated in FIG. 44 is obtained. Second frame member 42 has a recess 42d. Recess 42d is a recess with a constant length in the vertical direction.

This may be transferred onto second support 52 and vibrated to spread the distribution of resin material 4. Resin distribution set 25 is formed, regardless of the presence or absence of the process of transferring onto second support 52 and applying vibration.

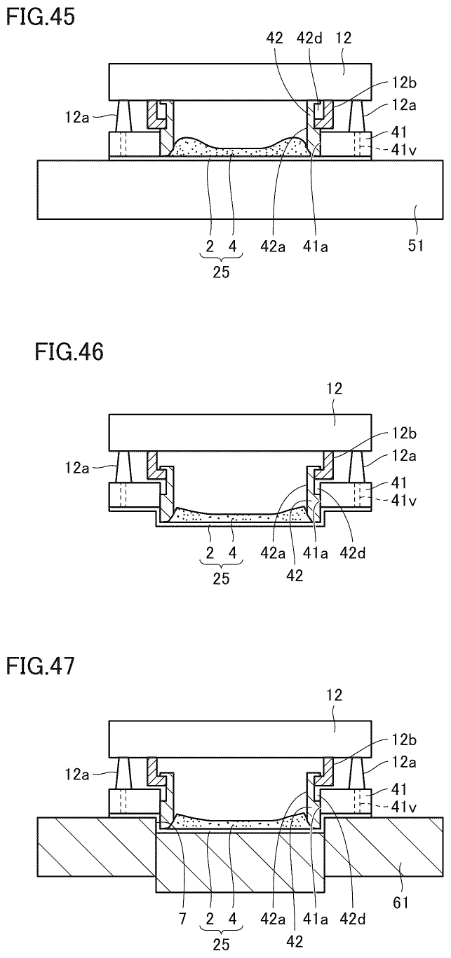

Next, process S3 of forming the state in which resin material 4 is placed above cavity 7 with release film 2 interposed therebetween will be described. In process S3, first, as illustrated in FIG. 45, conveying device 12 inserts the tip of hook 12b into recess 42d. In the present embodiment, conveying device 12 includes hook 12b. Hook 12b is displaceable in the horizontal direction. Next, as illustrated in FIG. 46, resin distribution set 25, first frame member 41, and second frame member 42 are lifted by conveying device 12. At this point in time, a part of release film 2 and resin material 4 may sag under the weight of second frame member 42 and the weight of resin material 4. Since recess 42d has a constant length in the vertical direction, second frame member 42 can be displaced downward while remaining engaged with hook 12b. At this point in time, the lowermost surface of resin distribution set 25 may be located lower than the lower surface of first frame member 41.

Next, as illustrated in FIG. 47, resin distribution set 25, first frame member 41, and second frame member 42 are placed onto lower mold 61 by conveying device 12. The above constitutes process S3. In practice, a part of release film 2 and resin material 4 may be fitted into cavity 7 immediately after being placed onto lower mold 61.

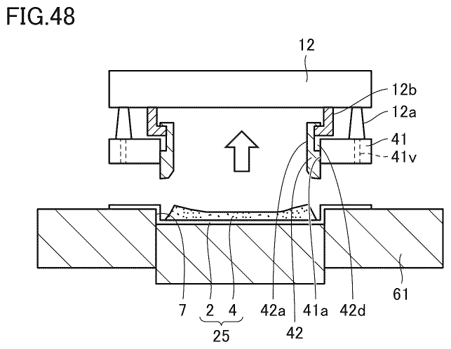

Next, as illustrated in FIG. 48, conveying device 12 moves upward. This causes second frame member 42 to move upward while remaining engaged with hook 12b. Resin distribution set 25 remains on lower mold 61. The above constitutes process S4 of positioning resin material 4, which is located in resin receiving portion, 10 into cavity 7.

Thereafter, process S5 of compression-molding resin material 4 to obtain resin molded body 8 is performed. Process S5 is performed in the same manner as that described in the first embodiment with reference to FIGS. 8 to 11.

In the present embodiment, since the central portion of resin distribution set 25 is pushed into cavity 7 using the downward displacement of second frame member 42 under its own weight, resin material 4 can be positioned in a desired location with high reliability.

Note that a combination of some of the embodiments may be employed as needed.

Note that the embodiments disclosed herein are illustrative in all respects and are not restrictive. The scope of the present invention is set forth by the claims, and the present invention is intended to include the claims, equivalents of the claims, and all modifications within the scope.

### APPENDIX 1

An electronic component manufacturing method for obtaining an electronic component in which a resin molded body and an object are integrally formed, the manufacturing method including:
forming a resin receiving portion by laying a release film on an upper surface of a first support;
forming a resin distribution set in which a resin material in granular, powder, or liquid form accumulates more thickly at a desired location than at other locations by feeding the resin material to the resin receiving portion;
lifting the resin distribution set including the release film and placing the resin distribution set onto a lower mold such that the resin receiving portion is aligned with a cavity provided in the lower mold in a shape corresponding to the resin molded body to form a state in which the resin material is placed above the cavity with the release film interposed therebetween;
covering an inner surface of the cavity with the release film and positioning the resin material located in the resin receiving portion into the cavity; and
compression-molding the resin material with the object in contact with the resin material located in the cavity to obtain the resin molded body.

### APPENDIX 2

The electronic component manufacturing method according to appendix 1, in which in the resin distribution set, the resin material accumulates more thickly at a near-peripheral portion of the resin receiving portion than at a central portion.

### APPENDIX 3

The electronic component manufacturing method according to appendix 1 or 2, in which
the forming the resin distribution set includes:
feeding the resin material into the resin receiving portion; and
vibrating a second support with the resin receiving portion placed on an upper surface of the second support to spread distribution of the resin material.

### APPENDIX 4

The electronic component manufacturing method according to appendix 3, in which a section of the upper surface of the second support corresponding to a center of the resin receiving portion is higher than other sections.

### APPENDIX 5

The electronic component manufacturing method according to any one of appendixes 1 to 4, in which
the forming the resin receiving portion includes positioning a first frame member with a first through hole corresponding to a shape of the cavity on the release film, and
the first through hole serves as the resin receiving portion.

### APPENDIX 6

The electronic component manufacturing method according to any one of appendixes 1 to 4, in which
the forming the resin receiving portion includes positioning a first frame member and a second frame member on the release film,
the first frame member has a first through hole corresponding to a shape of the cavity,
the second frame member is positioned within the first through hole and has a second through hole,
the second through hole serves as the resin receiving portion, and
the positioning the resin material into the cavity includes pushing the release film into the cavity by lowering the second frame member relative to the first frame member.

### APPENDIX 7

The electronic component manufacturing method according to appendix 2, in which the resin material is positioned at the central portion to have either a constant thickness or a constant weight per unit area, the near-peripheral portion includes a portion where the resin material is positioned with a greater thickness than at the central portion and a portion where the resin material is positioned with a smaller thickness than at the central portion, an average thickness or a weight per unit area of the resin material at the near-peripheral portion is greater than or equal to 0.8 times the thickness or the weight per unit area of the resin material at the central portion, and widths of the near-peripheral portion in X and Y directions are less than or equal to 25% of lengths of the resin receiving portion in the X and Y directions, respectively, as viewed from above.

### APPENDIX 8

An electronic component manufacturing device for obtaining an electronic component in which a resin molded body and an object are integrally formed, the manufacturing device including:
a resin distribution set forming device that forms a resin distribution set in which a resin material in granular, powder, or liquid form accumulates more thickly at a desired location than at other locations by feeding the resin material to a resin receiving portion formed on a release film;
a conveying device that lifts the resin distribution set including the release film and places the resin distribution set onto a lower mold such that the resin receiving portion is aligned with a cavity provided in the lower mold in a shape corresponding to the resin molded body; and
a compression molding device that compression-molds the resin material with the object in contact with the resin material located in the cavity,
in which when the conveying device places the resin distribution set onto the lower mold, an inner surface of the cavity is covered with the release film, and the resin material located in the resin receiving portion is positioned into the cavity.

### APPENDIX 9

The electronic component manufacturing device according to appendix 8, in which the resin distribution set forming device forms the resin distribution set such that the resin material accumulates more thickly at a near-peripheral portion of the resin receiving portion than at a central portion.

### APPENDIX 10

The electronic component manufacturing device according to appendix 8 or 9, in which
the resin distribution set forming device includes:
a first support on which the release film is placed to form the resin receiving portion;
a feeding device that feeds the resin material into the resin receiving portion; and
a second support having an upper surface, and
the second support is vibrated with the resin receiving portion placed on the upper surface of the second support to spread distribution of the resin material.

### APPENDIX 11

The electronic component manufacturing device according to appendix 10, in which a section of the upper surface of the second support corresponding to a center of the resin receiving portion is higher than other sections.

### APPENDIX 12

The electronic component manufacturing device according to any one of appendixes 8 to 11, in which
the resin distribution set forming device includes a first frame member that is positioned on the release film,
the first frame member has a first through hole corresponding to a shape of the cavity, and
the first through hole serves as the resin receiving portion.

### APPENDIX 13

The electronic component manufacturing device according to any one of appendixes 8 to 11, in which
the resin distribution set forming device includes a first frame member and a second frame member that are positioned on the release film,
the first frame member has a first through hole corresponding to a shape of the cavity,
the second frame member is positioned within the first through hole and has a second through hole,
the second through hole serves as the resin receiving portion, and
the manufacturing device includes a mechanism that pushes the release film into
the cavity by lowering the second frame member relative to the first frame member.

### REFERENCE SIGNS LIST

1: object, 2: release film, 4: resin material, 5: board, 6: component, 7: cavity, 8: resin molded body, 10: resin receiving portion, 11: feeding device, 12: conveying device, 12a: suction nozzle, 12b: hook, 13: near-peripheral portion, 14: central portion, 25: resin distribution set, 30: resin distribution set forming device, 31: first portion, 32: second portion, 33: compression molding device, 41: first frame member, 41a: first through hole, 41v: suction hole, 42: second frame member, 42a: second through hole, 42c, 42d: recess, 51: first support, 51a: upper surface (of first support), 52: second support, 52a: upper surface (of second support), 53: vibration applying device, 54, 54i, 54j, 54k, 54n: plate member, 60: mold, 61: lower mold, 61a: lower mold first portion, 61b: lower mold second portion, 62: upper mold, 80: electronic component, 101, 102, 103: manufacturing device.

1. An electronic component manufacturing method for obtaining an electronic component in which a resin molded body and an object are integrally formed, the manufacturing method comprising:
forming a resin receiving portion by laying a release film on an upper surface of a first support;
forming a resin distribution set by feeding a resin material in granular, powder, or liquid form to the resin receiving portion to create a non-uniform distribution, wherein the resin material has a greater thickness at a predetermined location than at other locations;
lifting the resin distribution set including the release film and placing the resin distribution set onto a lower mold such that the resin receiving portion is aligned with a cavity provided in the lower mold in a shape corresponding to the resin molded body to form a state in which the resin material is placed above the cavity with the release film interposed therebetween;
covering an inner surface of the cavity with the release film and positioning the resin material located in the resin receiving portion into the cavity; and
compression-molding the resin material with the object in contact with the resin material located in the cavity to obtain the resin molded body.

2. The electronic component manufacturing method according to claim 1, wherein in the resin distribution set, the predetermined location is at a near-peripheral portion of the resin receiving portion.

3. The electronic component manufacturing method according to claim 1, wherein
forming the resin distribution set includes:
placing the resin receiving portion on an upper surface of a second support; and
vibrating the second support with the resin receiving portion placed on an upper surface of the second support to spread distribution of the resin material.

4. The electronic component manufacturing method according to claim 3, wherein a section of the upper surface of the second support corresponding to a center of the resin receiving portion is higher than other sections.

5. The electronic component manufacturing method according to claim 1, wherein
forming the resin receiving portion includes positioning a first frame member with a first through hole corresponding to a shape of the cavity on the release film, and
first through hole serves as the resin receiving portion.

6. The electronic component manufacturing method according to claim 1, wherein
forming the resin receiving portion includes positioning a first frame member and a second frame member on the release film,
first frame member has a first through hole corresponding to a shape of the cavity,
the second frame member is positioned within the first through hole and has a second through hole,
the second through hole serves as the resin receiving portion, and
positioning the resin material into the cavity includes pushing the release film into the cavity by lowering the second frame member relative to the first frame member.

7. The electronic component manufacturing method according to claim 2, wherein the resin material is positioned at the central portion to have either a constant thickness or a constant weight per unit area, the near-peripheral portion includes a portion where the resin material is positioned with a greater thickness than at the central portion and a portion where the resin material is positioned with a smaller thickness than at the central portion, an average thickness or a weight per unit area of the resin material at the near-peripheral portion is greater than or equal to 0.8 times the thickness or the weight per unit area of the resin material at the central portion, and widths of the near-peripheral portion in X and Y directions are less than or equal to 25% of lengths of the resin receiving portion in the X and Y directions, respectively, as viewed from above.

8. An electronic component manufacturing device for obtaining an electronic component in which a resin molded body and an object are integrally formed, the manufacturing device comprising:
a resin distribution set forming device that forms a resin distribution set by feeding a resin material in granular, powder, or liquid form to the resin receiving portion to create a non-uniform distribution, wherein the resin material has a greater thickness at a predetermined location than at other locations;
a conveying device that lifts the resin distribution set including the release film and places the resin distribution set onto a lower mold such that the resin receiving portion is aligned with a cavity provided in the lower mold in a shape corresponding to the resin molded body; and
a compression molding device that compression-molds the resin material with the object in contact with the resin material located in the cavity,
wherein when the conveying device is configured to place the resin distribution set onto the lower mold such that the release covers an inner surface of the cavity, thereby positioning the resin receiving portion into the cavity.

9. The electronic component manufacturing device according to claim 8, wherein the resin distribution set forming device forms the resin distribution set such that the resin material accumulates more thickly at a near-peripheral portion of the resin receiving portion than at a central portion.

10. The electronic component manufacturing device according to claim 8, wherein
the resin distribution set forming device includes:
a first support on which the release film is placed to form the resin receiving portion;
a feeding device that feeds the resin material into the resin receiving portion; and
a second support having an upper surface, and
the second support is vibrated with the resin receiving portion placed on the upper surface of the second support to spread distribution of the resin material.

11. The electronic component manufacturing device according to claim 10, wherein a section of the upper surface of the second support corresponding to a center of the resin receiving portion is higher than other sections.

12. The electronic component manufacturing device according to claim 8, wherein
the resin distribution set forming device includes a first frame member that is positioned on the release film,
the first frame member has a first through hole corresponding to a shape of the cavity, and the first through hole serves as the resin receiving portion.

13. The electronic component manufacturing device according to claim 8, wherein
the resin distribution set forming device includes a first frame member and a second frame member that are positioned on the release film,
the first frame member has a first through hole corresponding to a shape of the cavity,
the second frame member is positioned within the first through hole and has a second through hole,
the second through hole serves as the resin receiving portion, and
the manufacturing device includes a mechanism that pushes the release film into the cavity by lowering the second frame member relative to the first frame member.

14. The electronic component manufacturing device according to claim 13, wherein the mechanism includes a hook included in the conveying device, the hook configured to engage a recess in the second frame member to control a vertical position of the second frame member.

15. An electronic component, comprising:
an object having a board and a plurality of electronic components mounted on the board; and
a resin molded body encapsulating the plurality of electronic components, wherein the resin molded body has a greater density at peripheral regions corresponding to the electronic components located at the periphery of the board than at a central region.
